(19) United States
(12) Patent Application Publication
(10) Pub. No.: US 2008/0214007 A1
(43) Pub. Date: Sep. 4, 2008

(54) METHOD FOR REMOVING DIAMOND LIKE CARBON RESIDUE FROM A DEPOSITION/ETCH CHAMBER USING A PLASMA CLEAN

(75) Inventors: Maria Wang, Plano, TX (US); Erika Leigh Shoemaker, Richardson, TX (US); Mary Roby, Plano, TX (US); Stuart Jacobsen, Frisco, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/681,582

(22) Filed: Mar. 2, 2007

(51) Int. Cl. H01L 21/311

(52) U.S. Cl. 438/694; 134/1.1; 257/E21.002

(57) ABSTRACT

Provided is a method for removing diamond like carbon residue from a deposition chamber. This method, in one embodiment, may include subjecting a deposition chamber including diamond like carbon residue to a plasma clean in the presence of fluorine containing gas and oxygen containing gas. The method may further include purging the deposition chamber having been subjected to the plasma clean with an inert gas, and pumping the deposition chamber having been subjected to the plasma clean.

### TECHNICAL FIELD OF THE INVENTION

The invention is directed, in general, to a method for cleaning a deposition/etch chamber and, more specifically, to a method for removing diamond like carbon residue from a deposition/etch chamber using a plasma clean.

### BACKGROUND OF THE INVENTION

The manufacture of certain types of substrates is a time-consuming process that often requires high levels of cleanliness. One example is the manufacture of certain types of substrates for integrated circuits. Many steps of manufacturing are conducted in various classes of so-called clean rooms, which have purified air flows to reduce the incidence of airborne particle contaminates. Nevertheless, wafers upon which semiconductor devices are fabricated can be rendered defective by contaminates introduced at various process steps, as opposed to the airborne particle contaminates.

In this regard, the manufacture of semiconductor devices typically involves process steps that are carried out on silicon wafers in process chambers, for example etching or deposition chambers. The level of particles in the process chambers must be controlled, or else particles can be deposited on the wafers, thereby causing defects and significantly reducing the effective yield.

In order to control the particle levels, process chambers are periodically subjected to a wet clean procedure, in which the chamber is disassembled or opened to the atmosphere, and then manually cleaned with a liquid (e.g., water or isopropyl alcohol) in order to remove films from the chamber walls which contribute to the particle count. After such a wet clean, there will be an initial high level of particles for a brief period, as a result of the fact that the chamber has been opened to the atmosphere. However, in the process of resuming production, the level of particles will drop to a very low level as a result of the fact that the films removed from the chamber during the wet clean are no longer present to contribute particles.

However, after a wet clean, and as production is carried out over time, the level of particles will begin to progressively increase, for example as films build back up on the chamber walls. In order to extend the time before the next wet clean must be carried out, it is possible to carry out one or more interim cleanings that do not require the use of liquids such as water or isopropyl alcohol. One such interim approach, sometimes known as a cycle purge or pump purge, involves pumping the chamber pressure down, then raising the pressure by filling the chamber with a gas such as nitrogen or argon, and then pumping the chamber pressure back down. This cycle may be repeated several times. Unfortunately, the pump purge interim approach, as well as other known interim approaches, are generally unable to remove residue that may form on the chamber walls during the etching or deposition of diamond like carbon layers.

Accordingly, what is needed is a method for cleaning a deposition or etching chamber having diamond like carbon residue therein that does not experience some of the drawbacks of previous methods.

### SUMMARY OF THE INVENTION

To address the above-discussed deficiencies of the prior art, provided is a method for removing diamond like carbon residue from a deposition/etch chamber. This method, in one embodiment, may include subjecting a deposition/etch chamber including diamond like carbon residue to a plasma clean in the presence of fluorine containing gas and oxygen containing gas. The method may further include purging the deposition/etch chamber having been subjected to the plasma clean with an inert gas, and pumping the deposition/etch chamber having been subjected to the plasma clean.

In an alternative embodiment, provided is a method for manufacturing a semiconductor device. The method for manufacturing the semiconductor device, without limitation, may include forming transistor devices over a substrate, wherein the transistor devices include gate structures and source/drain regions, and depositing a layer of diamond like carbon material over the substrate. The process for depositing the layer of diamond like carbon material may include placing the substrate having the transistor devices within a reactive ion etching chamber, providing a gas mixture to the reactive ion etching chamber, the gas mixture comprising CH₄, and generating a plasma within the reactive ion etching chamber having the gas mixture therein to form the layer of diamond like carbon material. In one embodiment, diamond like carbon residue forms on a surface within the reactive ion etching chamber as a result of depositing the layer of diamond like carbon material. Thereafter, the substrate having the layer of diamond like carbon material may be removed from the reactive ion etching chamber, and at least a portion of the diamond like carbon residue may be eliminated from the surface within the reactive ion etching chamber, for example as described above.

### BRIEF DESCRIPTION OF THE DRAWINGS

For a more complete understanding of the invention, reference is now made to the following descriptions taken in conjunction with the accompanying drawings, in which:

FIG. 1 illustrates a flow diagram depicting one embodiment of a method for manufacturing a semiconductor device.

FIG. 2 illustrates a chamber, for example a reactive ion etch (“RIE”) chamber, as might be used in one or more embodiments disclosed herein; and

FIG. 3 illustrates an alternative embodiment of the disclosure.

### DETAILED DESCRIPTION

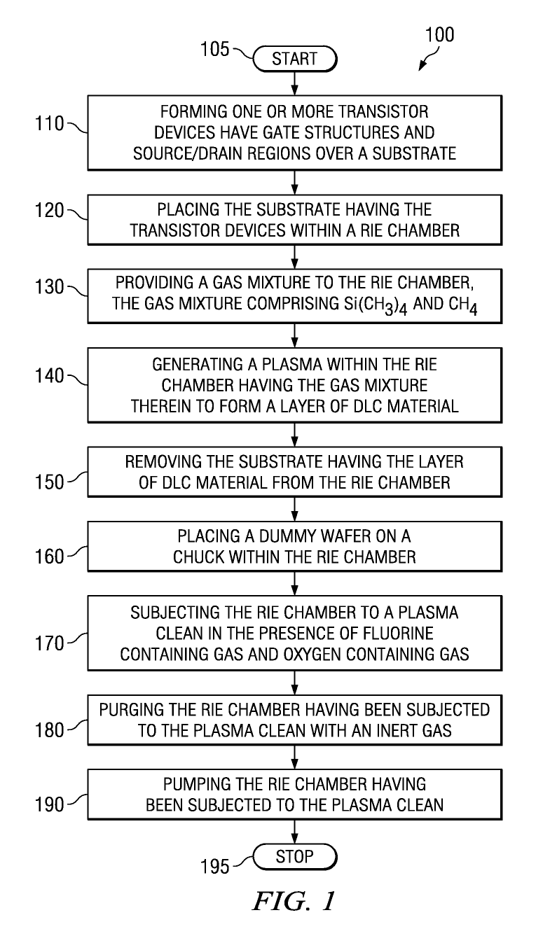

FIG. 1 illustrates a flow diagram 100 depicting one embodiment of a method for manufacturing a semiconductor device. The flow diagram 100, in addition to the method for manufacturing a semiconductor device, includes a subset including a method for removing diamond like carbon residue from a deposition/etch chamber. Accordingly, the flow diagram 100 should not be used to limit the disclosure to any specific steps. It should additionally be noted that, in certain embodiments, the order of steps 110-190 may change. Accordingly, flow diagram 100 denotes no specific order, as well as can be repeated any number of times.

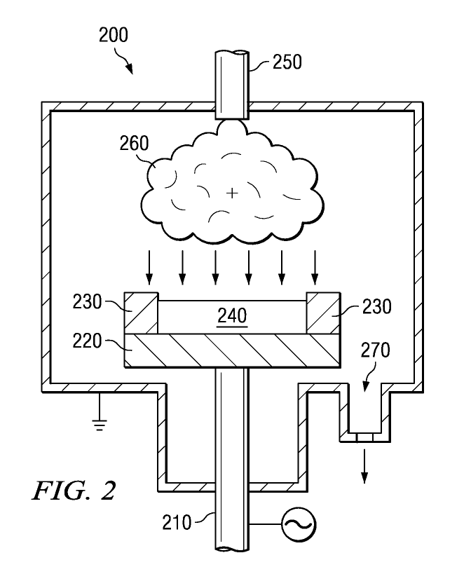

FIG. 2 illustrates a chamber 200, for example a reactive ion etch (“RIE”) chamber, as might be used in one or more embodiments disclosed herein. The chamber 200, in one embodiment, is a model P5000MxP+ chamber manufactured by Applied Materials (“AMAT”). Nevertheless, it is within the scope of this disclosure to use any suitable mainframe and RIE chamber, including, among others, AMAT's Centura system with 3MxP+ chambers.

The chamber 200 of FIG. 2 includes a cathode 210 on which an electrostatic chuck (“e-chuck”) 220 sits. In this example application, the chuck 220 is mainly anodized aluminum with a polyimide surface. However, the chuck 220 may comprise other materials, such as a ceramic material, and remain within the disclosure. Accordingly, the disclosure should not be limited to any specific chuck 200 material.

Located on the chuck 220 is a focus ring 230 (e.g., a quartz focus ring in one embodiment). In the illustrated embodiment, the focus ring 230 has a roughened surface. The roughened surface, as one skilled in the art might expect, helps residue (e.g., from various deposition or etching steps) to adhere thereto. Because the residue adheres to the roughened surface of the focus ring 230, the residue is less likely to slough off during the processing of one or more substrates.

The chamber 200 of FIG. 2 is a parallel plate reactor with the RF biased to the cathode 210. The cathode 210 is attached to the chuck 220 that holds one or more wafers 240, whether they are actual device wafers or dummy wafers. During chamber 200 operation, precursor gases enter the chamber 200 through gas inlet 250. When the chamber 200 has proper power and pressure applied (as described below) to the precursor gases, a plasma 260 (e.g., a positively charged plasma) may be formed in the space between the gas inlet 250 and the cathode 210. After the deposition/etching process is complete, or alternatively after cleaning the chamber 200 using the process disclosed below, excess gases or residue may exit the chamber 200 through outlet 270.

Referring back to FIG. 1, with continued reference to FIG. 2, flow diagram 100 begins in a start step 105. Thereafter, in a step 110, one or more transistor devices may be formed over a substrate. Any suitable manufacturing techniques may be used to form the transistor devices. For instance, in one embodiment conventional deposition, patterning and implantation techniques are used to form the gate structures and source/drain regions of the transistor devices. Other manufacturing techniques could also be used.

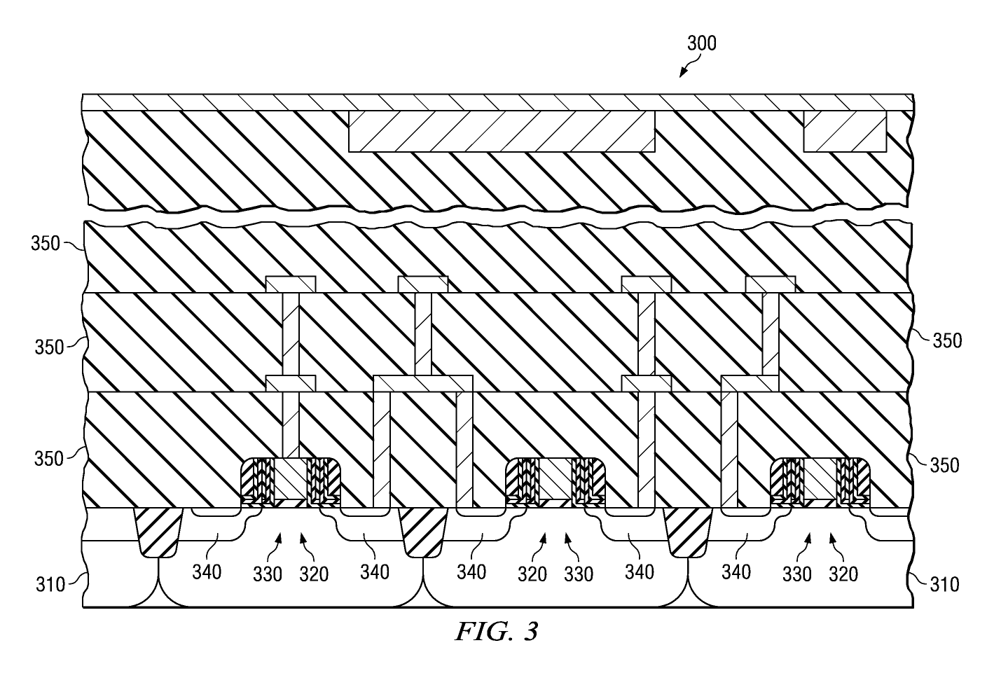

Thereafter, in steps 120-140, a layer of diamond like carbon (DLC) material may be deposited over the substrate having the transistor devices. In an example application, the layer of DLC material is used in thermal inkjet print heads, as described in U.S. Pat. No. 6,046,758 incorporated herein by reference and not admitted to be prior art with respect to the present disclosure by its mention in this section. However, other example applications include using the layer of DLC material as an inter-level dielectric material in a semiconductor device (see FIG. 3 below), using the layer of DLC material as a protective overlay or passivation layer in a semiconductor device, as well as using the layer of DLC material as a hard mask layer or etch stop layer in the formation of a semiconductor device. Other undisclosed uses may additionally be envisioned.

The process for depositing the layer of DLC material begins in a step 120. Step 120 includes placing the substrate having the transistor devices within a chamber (e.g., the chamber 200). Those skilled in the art understand the steps and precautions that need be taken to place the substrate within the chamber 200, including placing the substrate (e.g., wafer 240 in this embodiment) on the chuck 220.

Thereafter, in a step 130, a gas mixture is provided to the chamber 200 using the gas inlet 250. In the given embodiment wherein the layer of DLC material is being deposited, the gas mixture comprises CH₄, among other possible gasses. This gas mixture would provide an undoped diamond like carbon layer. Alternatively, the layer of DLC material may be a silicon-doped diamond like carbon layer, wherein the gas mixture might comprise Si(CH₃)₄ and CH₄. Moreover, the layer of DLC material may be a titanium-doped diamond like carbon layer. In such an embodiment, a suitable gas mixture including CH₄ and a titanium containing gas might be used. Therefore, the gas mixture would likely be tailored to accommodate each of these different layers of DLC material.

In a step 140, a plasma 260 is generated within the chamber 200 to form the layer of DLC material. Those skilled in the art of plasma etching/depositing understand the conditions required to create the appropriate plasma 260. Nevertheless, additional process conditions may be found in previously mentioned U.S. Pat. No. 6,046,758. It should be noted the steps 130 and 140 may be conducted in any order, including performing step 140 prior to step 130.

In a subsequent step 150, the substrate may be removed from the chamber 200. Those skilled in the art understand the steps and precautions that need be taken to remove the substrate from the chamber 200, including breaking vacuum and gently removing the substrate (e.g., wafer 240 in this embodiment) from the chuck 220.

It should be noted that in certain optional embodiments the substrate may be subjected to a reactive ion etch to pattern or otherwise affect the layer of DLC material during a subsequent process step (post DLC deposition). In this embodiment, a fluorine containing gas, such as SF₆, might be used to pattern or otherwise affect the layer of DLC material. Further details regarding the reactive ion etching of the layer of DLC material may be found in U.S. patent application Ser. No. 11/681,483, (Atty. Docket No. TI 38757) entitled A PROCESS FOR REACTIVE ION ETCHING A LAYER OF DIAMOND LIKE CARBON, which was filed concurrently herewith (e.g., Mar. 2, 2007), has the same inventors, and is incorporated herein by reference as is reproduced in its entirety. It should also be noted that the plasma clean process described below can be implemented not only post diamond like carbon deposition but also post patterned diamond like carbon etch, as both diamond like carbon deposition and etch can be processed within the same chamber 200.

It should be noted that steps 110-150 may be conducted many different times before moving to later steps. For instance, it may take many repetitions of steps 110-150, or any subset thereof, before enough DLC residue exists on the walls of the chamber 200 to require plasma cleaning the chamber 200. Nevertheless, the plasma cleaning of the chamber, as will be discussed in detail below, is a relatively quick process, and thus can be conducted often without materially affecting the throughput of the manufacturing process. Accordingly, steps 110-150 need not always be repeated.

After removing the substrate from the chamber 200, diamond like carbon residue remaining on the focus ring 230 within the chamber 200 or the walls of the chamber 200 may be removed in steps 160-190. The term “diamond like carbon residue” as used throughout this disclosure means any undesirable residue that may exist within the chamber 200 as a result of deposition or etching a layer of DLC material. In those instances wherein the layer of DLC material is a silicon-doped layer of DLC material, the residue may include large amounts of silicon. In those instances wherein the layer of DLC material is a titanium-doped layer of DLC material, the residue may include large amounts of titanium. Other residue particles may exist in addition to the silicon and titanium.

The process of removing the DLC residue may begin in an optional step 160, wherein a dummy wafer (e.g., substrate 240 in an embodiment) is placed on the chuck 220 within the chamber 200. Step 160 is generally desired when the chuck 220 comprises a material that may be affected by the plasma clean. For instance, in those embodiments wherein the chuck comprises an etch impervious material, such as ceramic, no dummy wafer is required. However, in those embodiments wherein the chuck comprises a material that might be affected by the plasma clean, a dummy wafer is desired.

The dummy wafer, without limitation, might comprise a silicon wafer having a silicon dioxide layer formed thereover. The silicon dioxide layer, in this embodiment, might have a thickness of about 1000 nm or greater. In an alternative embodiment, the dummy wafer might comprise a silicon wafer having an Al₂O₃ layer formed thereover. It is believed that the oxygen in the silicon dioxide or Al₂O₃ layers may assist in the removal of the undesirable DLC residue. Nevertheless, a film of any thickness and a dummy wafer comprised of any material, particularly one having high selectivity to the fluorine and oxygen based plasma clean chemistry, could be used.

In a step 170, the chamber 200 may be subjected to a plasma clean in the presence of fluorine containing gas and oxygen containing gas to remove at least a portion of the DLC residue. For example, once the plasma clean is initiated, the DLC residue (Siₓ, Cₓ, Hₓ, etc.) that coats the inside of the chamber 200 reacts with the fluorine and oxygen containing gasses to form volatile compounds (SiFₓ, CFₓ, COₓ, HFₓ, etc.) that are subsequently pumped out of the chamber 200.

The fluorine containing gas, in one embodiment, comprises SF₆. In an alternative embodiment, the fluorine containing gas comprises CF₄. It is believed that the SF₆ gas may provide better removal of the DLC residue than the CF₄ gas. Nevertheless, SF₆ gas and CF₄ gas, as well as other fluorine containing gases, are within the purview of the disclosure. The oxygen containing gas, in one embodiment, comprises O₂. In an alternative embodiment, the oxygen containing gas comprises N₂O. Additionally, other oxygen containing gasses might be used. Moreover, in one particular embodiment the fluorine containing gas is SF₆ and the oxygen containing gas is O₂.

A variety of operating conditions for the plasma clean are within the scope of this disclosure. For example, any suitable pressure level ranging from about 100 mT to about 500 mT may be used. Additionally, the power may range from about 100 watts to about 1200 watts, and duration of the clean may vary depending on the amount of residue existing in the chamber. For example, the duration may range from about 30 seconds to about 300 seconds. In addition, the total gas flow might range from about 100 sccm to about 1000 sccm.

In one embodiment, a flow rate ratio of the fluorine containing gas to the oxygen containing gas ranges from about 1:1 to about 10:1. For example, when the fluorine containing gas comprises SF₆ it might have a flow rate ranging from about 80 sccm to about 800 sccm. Alternatively, when the fluorine containing gas comprises CF₄ it might have a flow rate ranging from about 100 sccm to about 1000 sccm. Additionally, when the oxygen containing gas comprise O₂ it might have a flow rate ranging from about 20 sccm to about 200 scam and when the oxygen containing gas comprise N₂O it might have a flow rate ranging from about 30 sccm to about 400 scam. The foregoing flow rates illustrate but one embodiment of the flow rates that might be used.

The plasma clean may further use an inert gas, in addition to the fluorine containing gas and oxygen containing gas. For example, an inert gas might be included with the other gases to help reduce fluorine from the fluorine containing gas from recombining with itself. The plasma clean may further use N₂ gas, in addition to the fluorine containing gas and oxygen containing gas. For example, the N₂ gas might be included with the other gases to help disassociate oxygen from the oxygen containing gas. In the example wherein N₂ gas is used, a flow rate ratio of the oxygen containing gas to the N₂ gas should range from about 7:1 to about 10:1.

The specific operating conditions, flow rates and gasses given above for the plasma clean have been tested and observed to provide superior results. For example, those operating conditions, flow rates and gasses given above allow the DLC residue to be quickly and effectively removed, as compared to certain operating conditions, flow rates and gasses outside of those disclosed above. Accordingly, the aforementioned operating conditions, flow rates and gasses provide significant advantages.

The residue resulting from the plasma clean that resides inside the chamber 200 is removed in steps 180-190. For example, in a step 180, the chamber 200 is purged. The purge loosens physical particles from the internal walls and other parts of the chamber by the force of pressure. In one embodiment, the parameters of the purge are a pressure ranging from about 200 mT to about 2000 mT, an inert gas (e.g., Ar, He, N₂ etc.) flow rate ranging from about 100 sccm to about 2000 sccm, for a duration from about 5 seconds to about 500 seconds.

Also, in the step 190, the chamber 200 may be pumped in order to remove the particles loosened from the chamber 200 walls and other chamber parts during the purge step 180. In one embodiment, the pump step 190 is performed with throttle fully open (“TFO”) for from about 10 seconds to about 100 seconds in order to create a sufficient vacuum within the chamber 200. Nevertheless, any suitable low pressure pump operation is within the scope of the disclosure. The chamber 200 might be pumped using the outlet 270.

In an alternative embodiment, a second purge step and second pump step are performed in the chamber 200. The parameters of the second purge step may be similar to the parameters of the first purge step 180. The second pump step, in contrast to the first pump step 190, may be performed longer, for example from about 15 seconds to about 150 seconds with TFO. Nevertheless, it is within the scope of the disclosure to have the second purge step differ from the first purge step 180, to omit the second purge and second pump steps, or to add additional purge or pump steps after the second pump step. After completing steps 180-190, the process could return to a previous step or end in the stop step 195.

FIG. 3 illustrates an alternative embodiment of the disclosure. For instance, FIG. 3 illustrates a semiconductor device 300 including a layer of diamond like carbon. The semiconductor device 300 includes transistor devices 320 located over a substrate 310. The transistor devices 320 in this embodiment include gate structures 330 and source/drain regions 340. Positioned over the transistor devices 320 are one or more inter-level dielectric layers 350. In the embodiment of FIG. 3, at least one of the one or more inter-level dielectric layers 350 comprise the layer of diamond like carbon. Additionally, the chamber used to form the layer of diamond like carbon may be cleaned using the disclosed plasma clean process.

While one or more of the inter-level dielectric layers 350 of FIG. 3 may comprise the layer of diamond like carbon, other features of the semiconductor device 300 may additionally comprise the layer of diamond like carbon. For example, any hard mask or etch stop layer used in the manufacture of the semiconductor device 300 may comprise the layer of diamond like carbon. Additionally, protective overlays or final passivation layers of the semiconductor device 300 (neither of which are clearly illustrated in FIG. 3) may comprise the layer of diamond like carbon. Other uses for the layer of diamond like carbon, are also envisioned.

Those skilled in the art to which the disclosure relates will appreciate that other and further additions, deletions, substitutions and modifications may be made to the described embodiments without departing from the scope herein.

What is claimed is:

1. A method for removing diamond like carbon residue from a deposition/etch chamber, comprising:
subjecting a deposition/etch chamber including diamond like carbon residue to a plasma clean in the presence of fluorine containing gas and oxygen containing gas;
purging the deposition/etch chamber having been subjected to the plasma clean with an inert gas; and
pumping the deposition/etch chamber having been subjected to the plasma clean.

2. The method as recited in claim 1 wherein the fluorine containing gas is SF₆.

3. The method as recited in claim 2 wherein a flow rate of the fluorine containing gas ranges from about 800 sccm to about 800 sccm.

4. The method as recited in claim 1 wherein the oxygen containing gas is O₂.

5. The method as recited in claim 4 wherein a flow rate of the oxygen containing gas ranges from about 20 sccm to about 200 sccm.

6. The method as recited in claim 1 wherein the fluorine containing gas is SF₆ and the oxygen containing gas is O₂.

7. The method as recited in claim 1 wherein the fluorine containing gas is CF₄.

8. The method as recited in claim 1 wherein the oxygen containing gas is N₂O.

9. The method as recited in claim 1 wherein subjecting includes subjecting using a pressure ranging from about 100 mT to about 500 mT, a power ranging from about 100 watts to about 1200 watts, and a total gas flow ranging from about 100 sccm to about 1000 sccm.

10. The method as recited in claim 1 wherein a flow rate ratio of fluorine containing gas to oxygen containing gas ranges from about 1:1 to about 10:1.

11. The method as recited in claim 1 further including subjecting in the presence of N₂ gas to help disassociate oxygen from the oxygen containing gas.

12. The method as recited in claim 1 further including subjecting in the presence of an inert gas to help fluorine from the fluorine containing gas from recombining with itself.

13. The method as recited in claim 1 wherein the diamond like carbon residue is silicon doped diamond like carbon residue.

14. The method as recited in claim 1 wherein the diamond like carbon residue is titanium doped diamond like carbon residue.

15. The method as recited in claim 1 further including placing a dummy wafer on a chuck located within the deposition/etch chamber prior to the subjecting.

16. The method as recited in claim 15 wherein the dummy wafer comprises a silicon dioxide layer.

17. The method as recited in claim 16 wherein the silicon dioxide layer has a thickness of about 1000 nm or greater.

18. The method as recited in claim 15 wherein the dummy wafer comprises Al₂O₃.

19. The method as recited in claim 1 wherein a chuck located within the deposition/etch chamber comprises a ceramic material, and further wherein no dummy wafer is located on the chuck during the subjecting.

20. The method as recited in claim 1 wherein the purging is a first purging and the pumping is a first pumping and further including additional purging and pumping steps.

21. A method for manufacturing a semiconductor device, including:
forming transistor devices over a substrate, wherein the transistor devices include gate structures and source/drain regions;
depositing a layer of diamond like carbon material over the substrate, including;
placing the substrate having the transistor devices within a reactive ion etching chamber;
providing a gas mixture to the reactive ion etching chamber, the gas mixture comprising CH₄; and
generating a plasma within the reactive ion etching chamber having the gas mixture therein to form the layer of diamond like carbon material, wherein diamond like carbon residue forms on an inner surface of the reactive ion etching chamber;
removing the substrate having the layer of diamond like carbon material from the reactive ion etching chamber; and
eliminating at least a portion of the diamond like carbon residue from the inner surface of the reactive ion etching chamber, including;
subjecting the reactive ion etching chamber to a plasma clean in the presence of fluorine containing gas and oxygen containing gas;
purging the reactive ion etching chamber having been subjected to the plasma clean with an inert gas; and
pumping the reactive ion etching chamber having been subjected to the plasma clean.

22. The method as recited in claim 21 further including reactive ion etching the layer of diamond like carbon material within the reactive ion etching chamber after the depositing.

23. The method as recited in claim 22 wherein reactive ion etching the layer of diamond like carbon material includes reactive ion etching using SF₆.

24. The method as recited in claim 21 wherein each of the forming and the depositing occur multiple times before the eliminating.

25. The method as recited in claim 21 wherein the gas mixture comprises Si(CH₃)₄ in addition to CH₄ to deposit a layer of silicon-doped diamond like carbon over the substrate.
